(19) United States
(12) Patent Application Publication
(10) Pub. No.: US 2009/0126780 A1
(43) Pub. Date: May 21, 2009

(54) Solar Cell and Method of Manufacturing a Transparent Cover Plate

(76) Inventor: Chang-Chih Sung, Taoyuan County (TW)

Correspondence Address: KAMRATH & ASSOCIATES P.A., 4825 OLSON MEMORIAL HIGHWAY, SUITE 245, GOLDEN VALLEY, MN, 55422, US

(21) Appl. No.: 11/940,349

(22) Filed: Nov. 15, 2007

(51) Int. Cl. H01L 31/042

(52) U.S. Cl. 136/251

(57) ABSTRACT

A solar cell and a manufacturing method of a transparent cover plate are provided. The solar cell has a receiving room and a transparent cover plate. At least a cell unit is located in the receiving room. The transparent cover plate is placed on the solar cell. The transparent cover plate includes a base plate and a structured plate. The structured plate is adhered to the base plate. The structured plate has a first surface that face to the cell unit. Pluralities of first structures are disposed on the first surface. The base plate has a second surface, which is an incident-plane of the transparent cover plate. The second surface is flat.

### BACKGROUND OF THE INVENTION

1. Field of the Invention

The present invention relates to a cell and particularly to a solar cell.

2. Description of the Prior Art

In recent years the greenhouse effect caused by discharge of carbon dioxide and soaring of oil price gradually make renewable energy a focus of the general public. At present the techniques related to renewable energy include solar energy, wind power, geothermal energy, hydraulic power, tidal power, ocean thermal energy conversion and biomass energy and the like. Among them the technique of solar energy is most widely adopted.

Refer to FIG. 1 for a conventional solar cell. The solar cell 10 has a receiving room 14 to hold a filler 17 and a plurality of polycrystal cells 16. The polycrystal cells 16 are connected in series through a conductive wire 18. The filler 17 is ethylene-vinyl acetate copolymer or the like. There is a glass cover plate 12 on an upper side of the solar cell 10. The glass cover plate 12 is flat and allows sunshine to pass through and project to the polycrystal cells 16. As the glass cover plate 12 will absorb and reflect sunshine, a portion of sunshine cannot project to the polycrystal cells. Hence the efficiency of the solar cell 10 decreases.

At present some published papers suggest to form patterns on the incident surface of the glass cover plate to reduce light reflection, thereby to increase the efficiency of the solar cell. However, forming patterns on the glass cover plate tends to accumulate dusts. This is especially true in deserts where dust storm frequently occurs. As a result the glass cover plate has to be washed and cleaned frequently. Maintenance cost is higher. Moreover, the size of the patterns generally is between 300 μm and 400 μm. Cleaning is difficult, and maintenance cost is much higher.

There are some techniques to form the patterns on the emission surface of the glass cover plate. But to date there is still no any reference exploring the subject of “Optimizing the pattern shape on the emission surface of the glass cover plate”. Moreover, the patterns usually are formed by embossing molten glass cover plate and cooling. During cooling the patterns tend to shrink and deform. Thus the resulting patterns have a lower precision, and the glass cover plate thus formed cannot achieve the desired effect.

Hence how to prevent dust accumulation and effectively maintain or increase the efficiency of solar cell is an issue remained to be resolved in the industry.

### SUMMARY OF THE INVENTION

It is an object of the present invention to provide a solar cell to prevent dust accumulation and maintain or increase efficiency thereof.

The solar cell according to the invention has a receiving room to hold at least one cell unit. A transparent cover plate is provided above the cell unit. The transparent cover plate includes a base plate and a structured plate that are adhered together. The structured plate has a first surface facing the cell unit. The first surface has a plurality of first structures formed thereon. The base plate has a second surface which is flat and serves as an incident surface of the transparent cover plate.

In one aspect the first structures abut one another.

In another aspect the structures have a spherical bottom surface formed at a radius R1. The first structures are arranged in multiple transverse rows abutting one another. Each transverse row consists of a plurality of the structures. The first structures of each transverse row are shifted by a distance R1 against a neighboring transverse row.

In yet another aspect the first surface has a plurality of second structures located between the first structures. Moreover, the second structures are formed in a convex lens structure, or formed in a shape of a pyramid or a semi-sphere. The second structures abut the first structures.

In yet another aspect the first structures are formed in a convex lens structure.

In yet another aspect the first structures are formed in a shape of a pyramid or a semi-sphere.

In yet another aspect the base plate is made from glass, and the structured plate is made from photo resin.

The invention also provides a method for manufacturing the transparent cover plate. The method includes the following steps: first, coating photo resin on a molding plate which has a plurality of third structures formed thereon so that the photo resin is disposed on the third structures; next, covering a base plate on the photo resin; then curing the photo resin to form a structured plate; finally removing the structured plate from the molding plate.

In one aspect of the aforesaid method the base plate is glass.

In the transparent cover plate of the solar cell of the invention, the structures are located inside the solar cell without exposing to external environments; hence they do not gather or accumulate pollutants from the external environments. As the structured plate is made from photo resin, forming is easier. Thus the shape and size of the first structures can be precisely controlled. And the resulting glass cover plate can achieve the desired effect easier.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a schematic view of a conventional solar cell.

FIG. 2 is a schematic view of a first embodiment of the solar cell of the invention.

FIG. 3 is a schematic view of the arrangement of the first structures of the first embodiment.

FIG. 4 is a side view of the first structures of the first embodiment.

FIG. 5 is a schematic view of light travel paths during passing through the first structures.

FIG. 6 is a schematic view of the arrangement of the first structures and second structures in a second embodiment of the invention.

FIG. 7 is a side view of the first structures and second structures.

FIG. 8 is a chart showing the efficiency of a solar cell of the second embodiment and a first comparison example when light incident angle is changed.

FIGS. 9A through 9E are schematic views of procedures for manufacturing the transparent cover plate of the first embodiment.

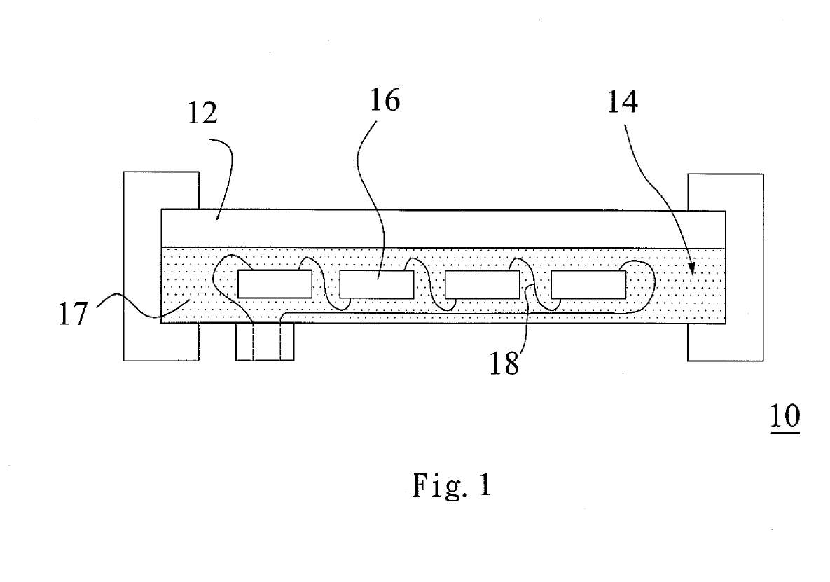

### DESCRIPTION OF THE PREFERRED EMBODIMENTS

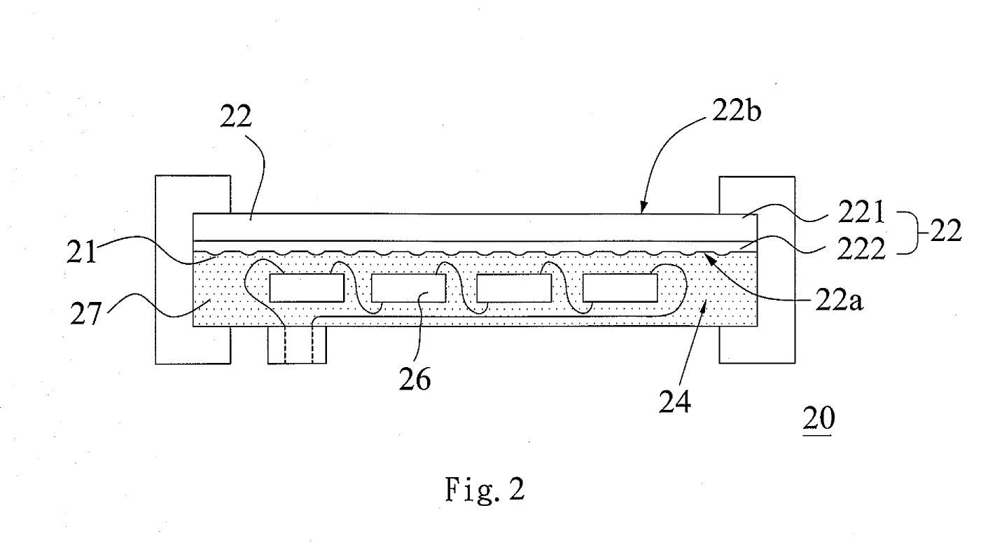

Refer to FIG. 2 for a first embodiment of the solar cell of the invention. The solar cell 20 has a receiving room 24 holding a filler 27 and a plurality of cell units 26. The filler 27 is ethylene-vinyl acetate copolymer or the like. The cell units 26 are a monocrystal cell in this embodiment, but may be a dye sensitized solar cell, polycrystal cell, or other devices that can convert solar energy to electric energy. There is a transparent cover plate 22 located above the cell units 26. The transparent cover plate 22 is made from glass and includes a base plate 221 and a structured plate 222. The structured plate 222 has a first surface 22a facing the cell units 26. The first surface 22a has a plurality of first structures 21 formed thereon. The base plate 221 has a second surface 22b which is flat and serves as an incident surface of the transparent cover plate 22. As the first structures 21 are not exposed to external environments, pollutants in the external environments do not accumulate on the first structures 21. Moreover, as the second surface 22b is flat, clearing the dusts accumulated thereon is easier.

The base plate 221 is made from glass. The structured plate 222 is made from photo resin. The first structure 21 is located on the structured plate 222. As the photo resin can be formed easier, the shape and size of first structures 21 can be formed precisely. Thus the resulting glass cover plate 22 can achieve the desired effect easier.

The material of the base plate 221, besides the glass, also may be other transparent materials such as Polymethyl Methacrylate (PMMA), Polycarbonate (PC), Polystyrene (PS), Polypropene (PP), Polyethylene (PE) or polyethylene terephthalate (PET).

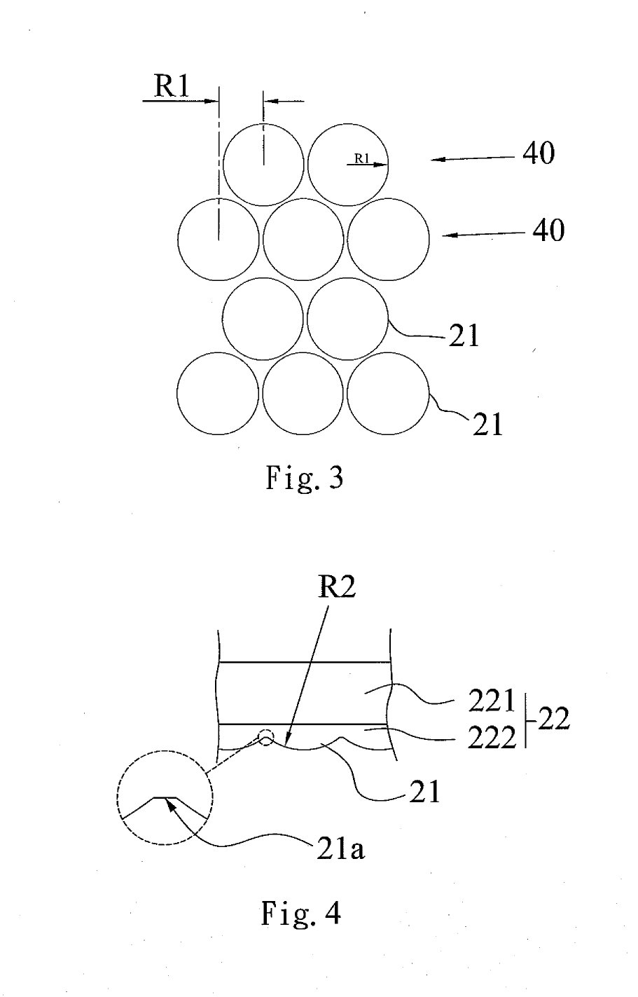

Refer to FIGS. 3 and 4 for the arrangement of the first structures in the first embodiment. The first structures 21 are formed in a convex lens structure and has a spherical bottom surface at a radius R1. In this embodiment, the radius R1 is 0.182 mm. The first structures 21 are laid as follow: a plurality of transverse rows 40 are formed; each transverse row 40 includes a plurality of first structures 21; the transverse rows 40 are abutting one another closely. The first structures 21 of each transverse row 40 are shifted by a distance R1 against a neighboring transverse row 40. The abutting closely means that they are adjacent to one another but not necessary forming physical contact. In practice, due to manufacturing process reason, a gap 21a often occurs between the first structures 21. Moreover, as the surface of the first structures 21 is spherical, it has a radius curvature for the spherical surface R2 which is 0.533 mm in this embodiment. While the first structures 21 previously discussed are abutting one another, to those skilled in the art, they also may be designed to be spaced from one another.

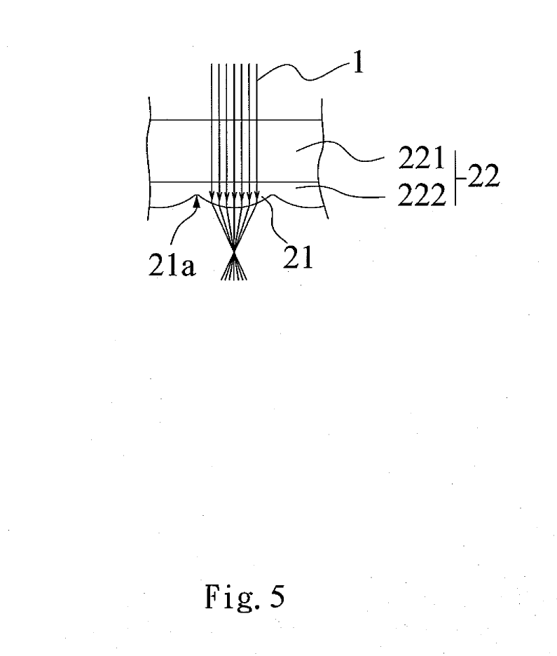

Referring to FIG. 5, the convex lens structure in the embodiment means that when light 1 projects vertically, it fully passes through the convex lens structure (such as the first structures 21 in the first embodiment) without any reflection. Moreover, due to the first structures 21 are a convex lens structure, it can converge light. Thus, overall speaking, the solar cell adopted the first embodiment can provide higher electricity generation efficiency.

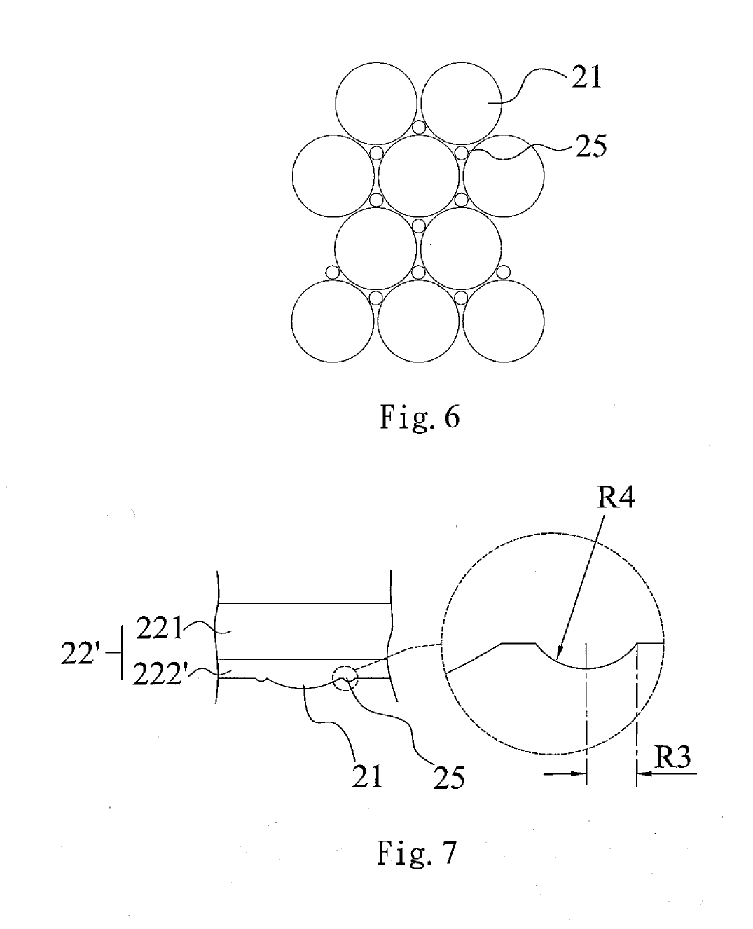

To those skilled in the art, a second structure may be disposed among the first structures 21. Refer to FIGS. 6 and 7 for a second embodiment. On the structured plate 222′ of the transparent cover plate 22′, second structures 25 are provided among the first structures 21 and abutting the first structures 21. The second structures 25 also are formed in a convex lens structure and have a bottom surface at a radius R3 of 0.03 mm. The surface of the second structures 25 is a spherical surface at a radius curvature R4 of 0.06 mm.

To facilitate manufacturing the first structures 21 and the second structures 25 are formed respectively in a spherical surface. However, they also may be formed in a non-spherical surface according to actual requirements, such as a pyramid shape or a semi-spherical shape. To those skilled in the art, the first structures 21 and the second structures 25 may also be designed in an indented downward fashion.

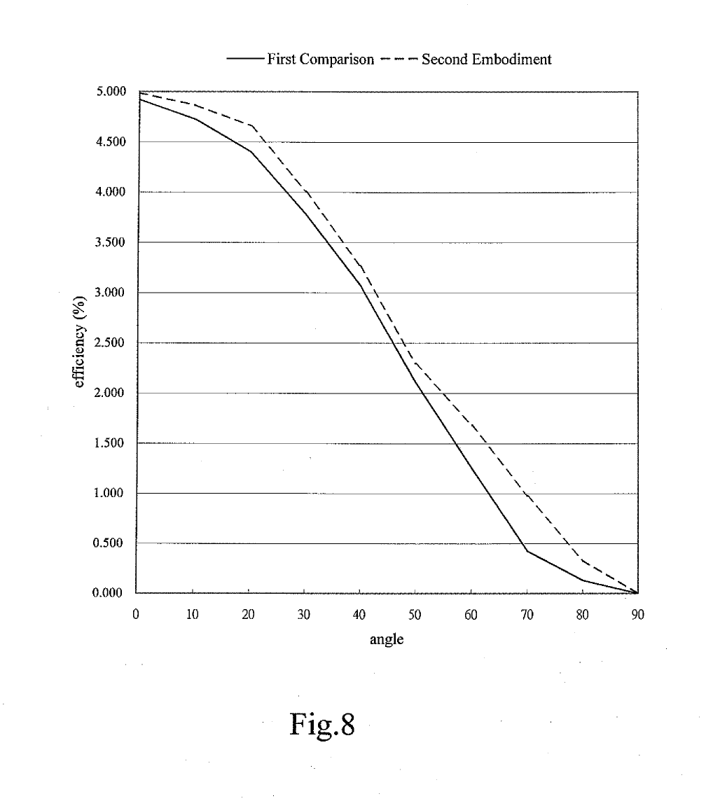

Refer to FIG. 8 for comparison of solar cell efficiency of the second embodiment against a first comparison example when the incident angle of the incident light is changed. The chart is made based on data obtained through a solar simulator. In the first comparison example a pattern glass produced by Yuen-chang Co. of Taiwan was used that has patterns directly formed on the glass. The patterns face the cell units. The chart indicates that whatever the incident angle the solar cell of the second embodiment has a better light conversion efficiency than the first comparison example.

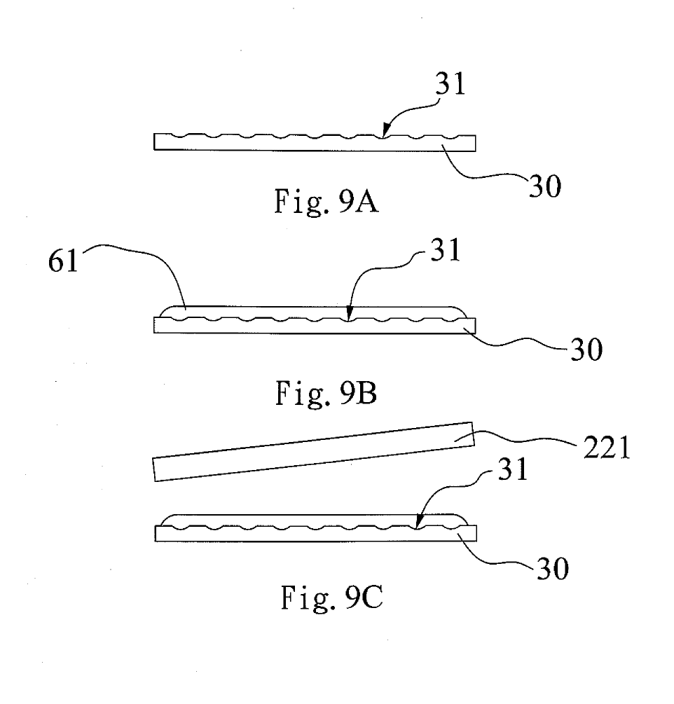

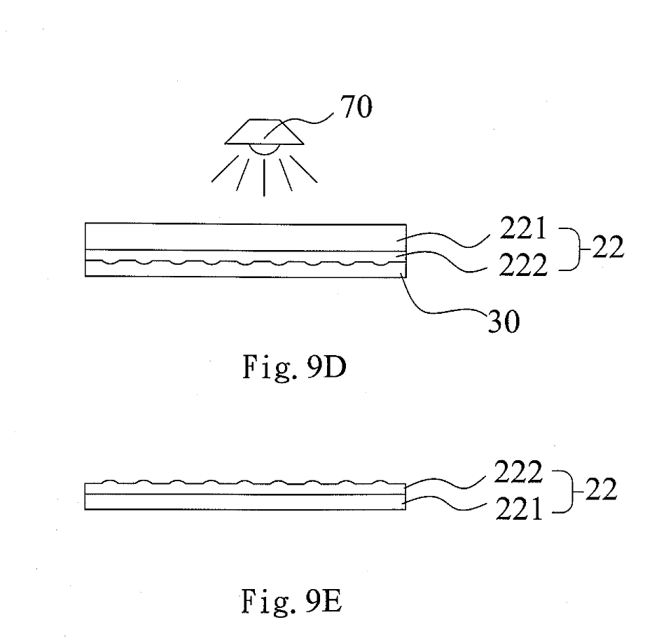

Refer to FIGS. 9A through 9E for the process steps of manufacturing the transparent cover plate of the first embodiment. First, referring to FIG. 9A, prepare a molding plate 30 with one surface forming a plurality of a plurality of third structures 31. Referring to FIG. 9B, dispense photo resin 61 onto the molding plate 30 and cover the third structures 31. Referring to FIG. 9C, cover the photo resin 61 with the base plate 221. Referring to FIG. 9D, project the photo resin 61 with an ultra violet lamp 70 to cure the photo resin 61 and form the structured plate 222. Referring to FIG. 9E, remove the structured plate 222 from the molding plate 30 to get the finished transparent cover plate 22.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

I claim:

1. A solar cell comprising a receiving room which holds at least one cell unit and a transparent cover plate located above the cell unit, wherein:
the transparent cover plate includes a base plate and a structured plate that are adhered together, the structured plate having a first surface facing the cell unit, the first surface having a plurality of first structures formed thereon, the base plate having a second surface which is flat and serves as a light incident surface of the transparent cover plate.

2. The solar cell of claim 1, wherein the first structures are abutting one another.

3. The solar cell of claim 1, wherein the first structures have respectively a spherical bottom surface at a radius R1, and are arranged in multiple transverse rows which are adjacent to one another, each transverse row consisting of a plurality of the first structures.

4. The solar cell of claim 3, wherein the first surface has a plurality of second structures located between the first structures.

5. The solar cell of claim 3, wherein the first structures of each row are shifted by a distance of the radius R1 against a neighboring row.

6. The solar cell of claim 1, wherein the first surface has a plurality of second structures located between the first structures.

7. The solar cell of claim 6, wherein the second structures are formed in a convex lens structure.

8. The solar cell of claim 6, wherein the second structures are formed in a shape of a pyramid or a semi-sphere.

9. The solar cell of claim 6, wherein the second structures are abutting the first structures.

10. The solar cell of claim 1, wherein the first structures are formed in a convex lens structure.

11. The solar cell of claim 1, wherein the first structures are formed in a shape of a pyramid or a semi-sphere.

12. The solar cell of claim 1, wherein the base plate is made from glass, the structured plate being made from photo resin.

13. A method for manufacturing a transparent cover plate, comprising:
coating photo resin on a molding plate which has a plurality of third structures formed thereon, the photo resin being dispensed onto the third structures;
covering the photo resin with a base plate;
curing the photo resin to form a structured plate; and
removing the structure plate from the molding plate.

14. The method of claim 13, wherein the base plate is made from glass.
